(19) United States
(12) Patent Application Publication
(10) Pub. No.: US 2016/0114867 A1
(43) Pub. Date: Apr. 28, 2016

(54) SYSTEM AND METHOD FOR MONITORING STABILITY OF A VESSEL

(71) Applicant: STABILITY SOLUTIONS INC., Delta (CA)

(72) Inventor: Peter James Nicol, Garden Bay (CA)

(73) Assignee: STABILITY SOLUTIONS INC., Delta, BC (CA)

(21) Appl. No.: 14/889,773

(22) PCT Filed: May 13, 2014
(86) PCT No.: PCT/CA2014/050446

§ 371 Date: Nov. 6, 2015

Related U.S. Application Data
(60) Provisional application No. 61/822,765, filed on May 13, 2013.

(51) Int. Cl. B63B 39/14; G01S 19/42; G01P 15/00; G01R 33/02; G01C 19/58; B63B 43/04; G01S 19/52

(52) U.S. Cl. CPC B63B 39/14; B63B 43/04; G01S 19/42; G01S 19/52; G01R 33/02; G01C 19/58; G01P 15/00

(57) ABSTRACT

An automated stability system which is accurate but simple enough to be implemented on small vessels such as fishing boats is provided. It provides this by integrating the measurements of a digital magnetometer, digital accelerometer, and digital gyroscope which are used to calculate the natural roll period of the vessel which in turn permits calculation of the GM (metacentric height). GPS may also be provided to provide for time and velocity correction.

### CROSS REFERENCE TO RELATED APPLICATION

The present application claims the benefits, under 35 U.S.C. §119(e), of U.S. Provisional Application Ser. No. 61/822,765 filed May 13, 2013 entitled “System and Method for Monitoring Stability of a Vessel” which is incorporated herein by this reference.

### TECHNICAL FIELD

The invention relates to the field of methods and apparatus for measuring and monitoring the stability of maritime vessels.

### BACKGROUND

Stability is the tendency of a vessel to rotate one way or the other, to right itself or overturn. Maintaining a marine vessel's stability is critical to avoid marine capsizings. Capsizing can occur when a vessel loses stability and thereby loses the ability to right itself. The standard measure of a vessel's stability is its metacentric height or GM value, defined as the distance between the vessel's centre of gravity G and its metacentre M. Safety regulations require a minimum metacentric height. The GM is calculated separately for transverse rolling motion and longitudinal pitching motion.

The rolling motion of a vessel has a natural frequency which, like a pendulum, is determined by the size of the mass and the length of the swing arm from which it is hanging in the gravitational field. The GM is essentially the length of that swing arm. The period of roll can be calculated from the GM and the radius of gyration of the vessel about the longitudinal axis through the centre of gravity.

The metacentre M of a vessel is, for the most part, fixed by the structure of the vessel. It is determined by the ratio between the inertia resistance of the vessel and the volume of the vessel. It can be calculated from KM, the vertical distance from the keel K to the metacentre M, from the following:

KM=KB+BM

BM=I/V
where KB is the distance from the keel K to the centre of buoyancy B, which is the centre of the volume of water which the hull displaces, BM is the distance from the centre of buoyancy B to the metacentre M, I is the second moment of the area of the waterplane in metres to the fourth power and V is the volume of the displacement in cubic metres.

The location of a vessel's centre of gravity G varies depending on a number of factors such as crew and cargo loading and movement, fuel consumption, icing on the vessel exterior, absorption of water, etc. A change in the position of G modifies the vessel's GM value and thus the vessel's stability. If G moves to a point above the metacentre M, GM becomes negative and the ship will not right itself and is in danger of capsizing. Since the GM can be constantly changing due to shifting crew and cargo, fuel consumption, icing and the like, for safety reasons it is important for the GM to be constantly monitored and recalculated taking into account the weight and distribution of fuel and cargo in the vessel.

An instrument capable of continuously calculating a vessel's GM is described in U.S. Pat. No. 1,860,345. The apparatus shown in that patent incorporates a gyroscope to measure the vessel's maximum rate of roll by determining the maximum force on the bearings of the gyroscope and a pendulum to measure the vessel's maximum angle of roll. The device is mechanically complicated, and works well only if carefully calibrated. U.S. Pat. No. 2,341,563 discloses an electro-mechanical device for determining the metacentric height of a ship which includes a pendulum. U.S. Pat. No. 3,982,424 also discloses an electro-mechanical device for determining the metacentric height of a ship which includes a roll sensor comprising a pendulous precision gyroscope. These systems are not automated for automatic monitoring and alarm.

U.S. Pat. Nos. 4,549,267 and 4,647,928 disclose computer implemented stability systems for marine vessels. The foregoing automated systems tend to be suitable for large ocean-going vessels and are complicated and expensive. Smaller boats also require the safety of stability systems so there is a need for an inexpensive and simple system which can be implemented on small vessels such as fishing boats.

The foregoing examples of the related art and limitations related thereto are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools and methods which are meant to be exemplary and illustrative, not limiting in scope. In various embodiments, one or more of the above-described problems have been reduced or eliminated, while other embodiments are directed to other improvements.

The embodiment therefore provides an automated stability system which is accurate but simple enough to be implemented on small vessels such as fishing boats. It provides this by integrating the measurements of a digital magnetometer, digital accelerometer, and digital gyroscope. Further, a GPS may be provided to provide for time and velocity correction.

In addition to the exemplary aspects and embodiments described above, further aspects and embodiments will become apparent by reference to the drawings and by study of the following detailed descriptions.

### BRIEF DESCRIPTION OF DRAWINGS

Exemplary embodiments are illustrated in referenced figures of the drawings. It is intended that the embodiments and figures disclosed herein are to be considered illustrative rather than restrictive.

FIG. 1 is a schematic diagram of a vessel provided with the system of the invention.

FIG. 2 is a flowchart showing the process for Autocorrelation for Roll Test and Dynamic Stability Monitoring.

FIG. 3 is a flowchart showing the process for Fast Fourier Transform using Welch's Method for Roll test and Dynamic Stability Monitoring.

FIG. 4 is a flowchart showing the process for Mean Incline Experiment Script.

FIG. 5 is a flowchart showing the process for Maximum Roll Angle Value.

FIG. 6 is a flowchart showing the process for calculating GM (Metacentric Height) from Roll Period.

FIG. 7 is a flowchart showing the process for power management.

### DESCRIPTION

Throughout the following description specific details are set forth in order to provide a more thorough understanding to persons skilled in the art. However, well known elements may not have been shown or described in detail to avoid unnecessarily obscuring the disclosure. Accordingly, the description and drawings are to be regarded in an illustrative, rather than a restrictive, sense.

The embodiment may incorporate portable computing devices to synchronize logistical vessel information to a networked computing infrastructure. A combination of embedded sensor networks using wireless networks, cellular, and satellite RF communication may be provided. These network technologies allow the automated exchange of data about a vessel, cargo, and environmental conditions.

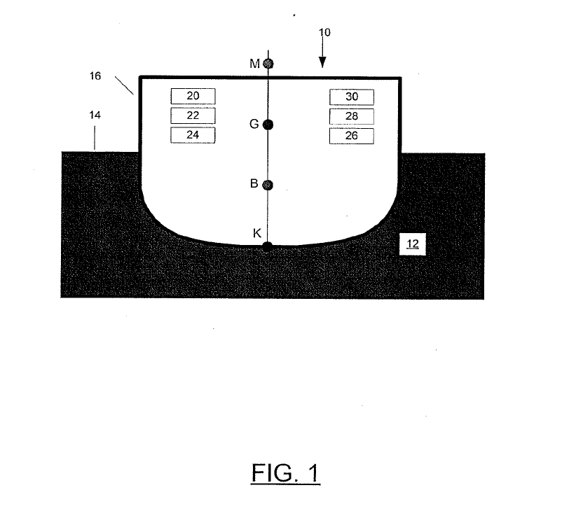

Looking at FIG. 1, a vessel 10 floating on a body of water 12 with a waterline 14 has a hull 16, keel K, centre of gravity G, metacenter M and centre of buoyancy B. The primary sensor is an Inertial Measurement Unit (IMU) 20 which provides inertial measurement. Global Positioning System/Global Navigation Satellite System (GPS/GNSS) receiver 24 provides positioning data. Multiple additional sensor devices 26 may be provided for sensing/providing additional information about fuel, ballast, and cargo stability and processor 28 carries out the calculations required for the system. Processor 28 has data storage 30. Visual or audible alarms (not shown) may also be provided.

IMU 20 is preferably a 10DOF IMU which incorporates four integrated multi-axis sensors: I) a triple-axis digital accelerometer, ii) a triple-axis digital gyroscope, iii) a triple-axis digital magnetometer and iv) a Barometric Pressure sensor. This provides 10 degrees of inertial measurement. Some typical chipsets used in these devices are: ADXL345 Datasheet; L3G4200D Datasheet; HMC5883L Datasheet; and BMP085 Datasheet. Any 10DOF sensor that fits the form factor and uses these or similar chips in their chipset will work in the system.

Processor 28 is preferably a cpu with at least 64M RAM or greater. GPS/GNSS device 24 is preferably a u-blox™ GPS/GNSS antenna module to provide standalone positioning including integrated chip antenna. The u-blox UP501 GPS receiver module with embedded GPS antenna enables navigation and location data. The GPS data is also used to provide a sealed and autonomous time stamp on the data. This is used for security and justifiability and to prevent tampering.

To communicate the sensor information to the processor 28, a battery operated wireless smart router 22 is used. This may be any smart USB router with suitable specifications and compatibility. Preferred is a Comfast: CF-WU710N which has a 50 m-200 m wireless range and USB interface. Smart router 22 can also connect a local mobile device or computer network to a global monitoring system. The Device 26 for sensing/providing additional information about fuel, ballast, and cargo stability may include Radar Sensors and other user defined transducers for measuring temperature, humidity, strain forces, and background radiation levels.

The data input from the sensors therefore includes: GPS location records, inertial motion, temperature, humidity, strain forces, and background radiation levels. A mapping system may automatically aggregate numerous vessels' sensor data, and navigation history. Additionally, such systems may be used independently or in conjunction with automated navigation or alarm notification systems.

A vessel's supervisory monitoring system may subscribe to a remote service architecture to update, extend, and/or modify the capabilities of the device while in operation. The network services may include commercial software applications, hardware provisioning, and maintenance asset management for remote location reporting.

The system extends the concept of an alarm to notify both local and remote operators of abnormal vessel operation and or condition. For example, these alarm states may report actions that exceed a vessel's stated capacity, indicate operational abnormalities, or general security alarm status.

The monitoring device may optionally include a portable standalone power source to ensure uninterrupted operation. The devices may also share information across a local wired or wireless network, and automatically select relevant information to exchange with a central service.

The magnetometer in IMU 20 is used to provide an absolute vector in space. Gyroscopic drift is compensated by this vector. The magnetometer may not sample fast enough (10 Hz) to prevent fold-over from higher frequency harmonics. It therefore permits over-sampling at 8 kHz while filtering out the higher part of the spectrum prior to entering the sample set. The accelerometer operates independently of magnetic declination, and therefore can also assist in compensating translational shifts via a weighted estimate of true pose in three-dimensional space.

The directional motion is analyzed using spectrum analysis and statistical methods to determine the dominant infrasonic wavelengths. This information is incrementally sampled into a calibrated numeric model of the vessel under ideal conditions to resolve safety margins. This information is compared against automated event trigger thresholds to issue warning alarms on local networks, and forward automated management notifications over wireless communication networks.

GPS device 24 serves two functions: as a correction factor in respect of the ship velocity and to correct clock drift. Synchronizing fleet information in a set of events globally requires that every machine share a near perfect approximation of the same time. Therefore, the GPS receivers' time synchronization can be used to constantly correct clock drift given that all machines share the same network time source without having to successively approximate the time across unstable network sources. Pose estimate samples are strictly ordered within this sub-second sample interval, and by tracking fixed latency intervals the system auto-corrects to closely match true time rather than a multi-tasking environment's estimate of time. Additionally, GPS location information can be used offline to reconstruct incremental positional changes, and assist sensor systems estimate of motion by knowing the approximate velocity vector. Correcting nonuniform sample intervals within the sampling window for each sensor allows reconstruction of concurrent events in time via interpolation methods to build a fixed interval sample. Thus, standard pose analysis methods like Sequential Monte Carlo are made more precise, and the derived spectrum analysis noise is diminished. Accordingly, analysis of torsional strains on a vessel, which would otherwise be difficult without being able to accurately cross-compare several pose estimates at differing locations for the same moment in time, can be done.

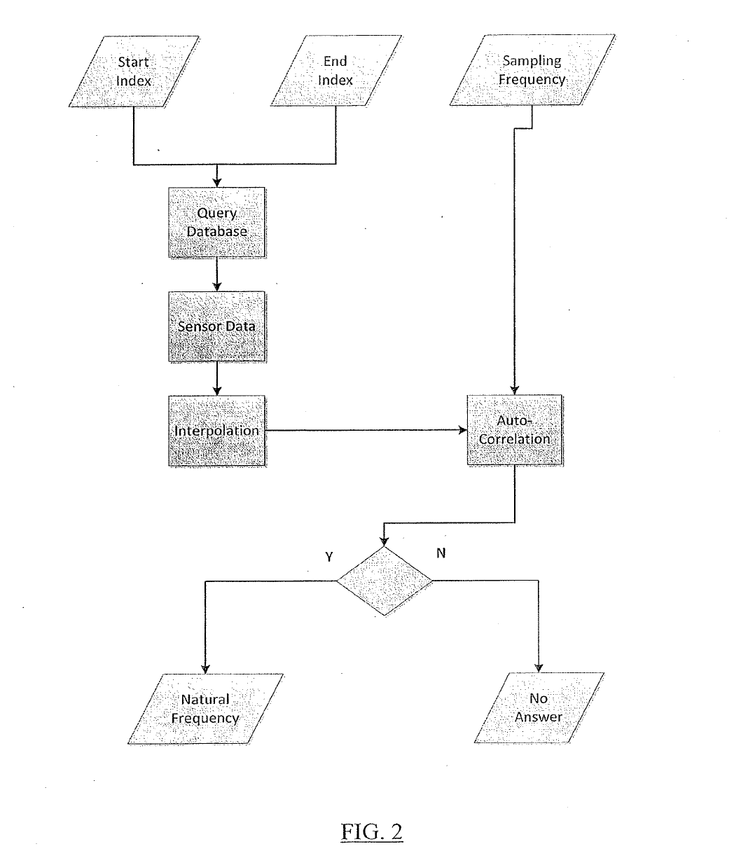

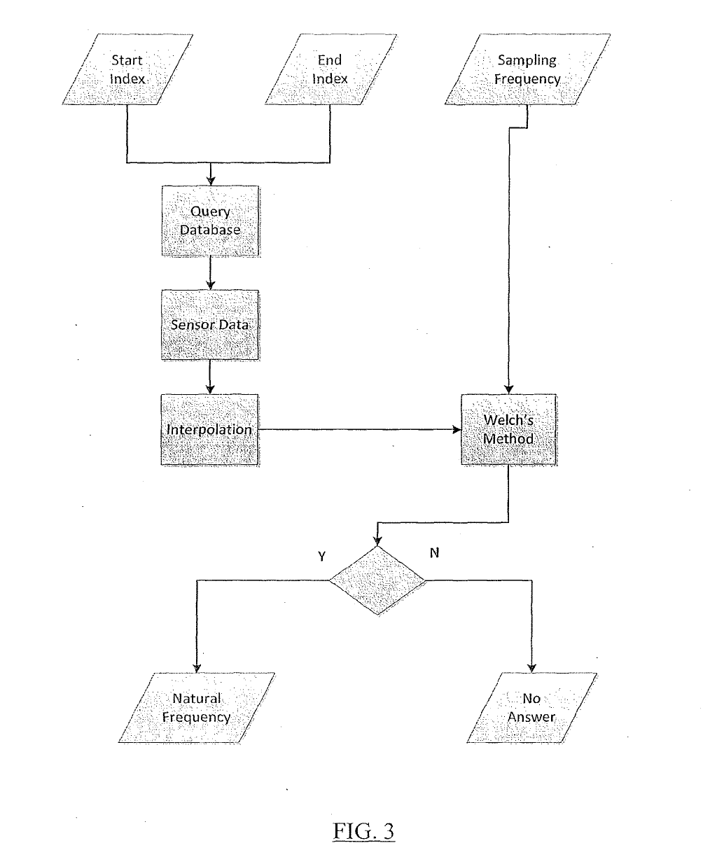

Looking at FIG. 2, this flowchart shows the first step carried out by processor 28, namely, Autocorrelation For Roll Test and Dynamic Monitoring. Database 32 is loaded and queried for sensor data from the Inertial Measurement Unit (IMU) 20. An interpolation routine is used to handle the data and prepare it for Autocorrelation using existing algorithms as explained in FIG. 3. Data from the MU 20 are used to calculate the natural roll frequency. The results returned are either a Natural Frequency or No Answer. This process is repeated until the Natural Frequency is known.

With reference to FIG. 3, a Fast Fourier Transform (FFT) using Welch's

Method is used for the roll test and dynamic stability measurement signals illustrated in FIG. 2. Database 30 is loaded and queried for sensor data from the MU 20. An interpolation routine is used to handle the data and prepare it for the Fourier Transform. The sampling frequency is used as an input for the Welch's Method routine. A routine that utilizes Welch's Method is used to handle the FFT. The results returned are either a Natural Frequency or No Answer. As noted above, this process is repeated until the Natural Frequency is known.

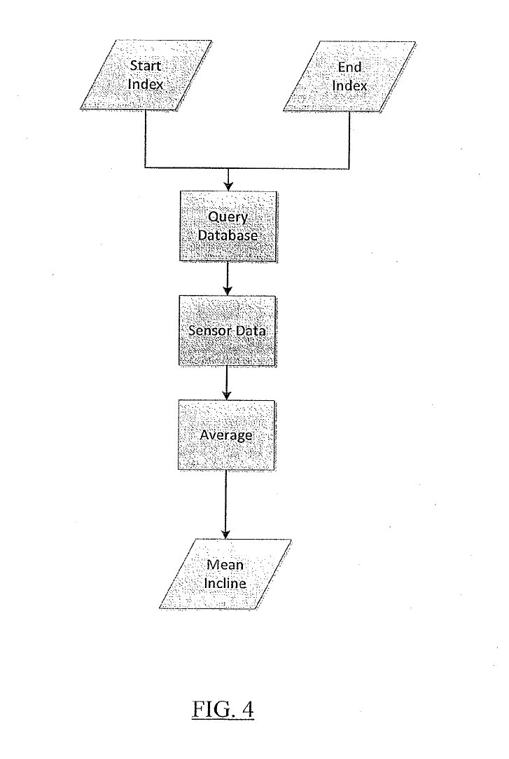

With reference to FIG. 4, Mean Incline Experiment Script may also be calculated. The database is loaded and queried for sensor data from the IMU 20. The data is passed to an Averaging routine that returns a Mean value for the vessel's incline. This incline experiment may be used to determine the length from the keel K to the centre of gravity G.

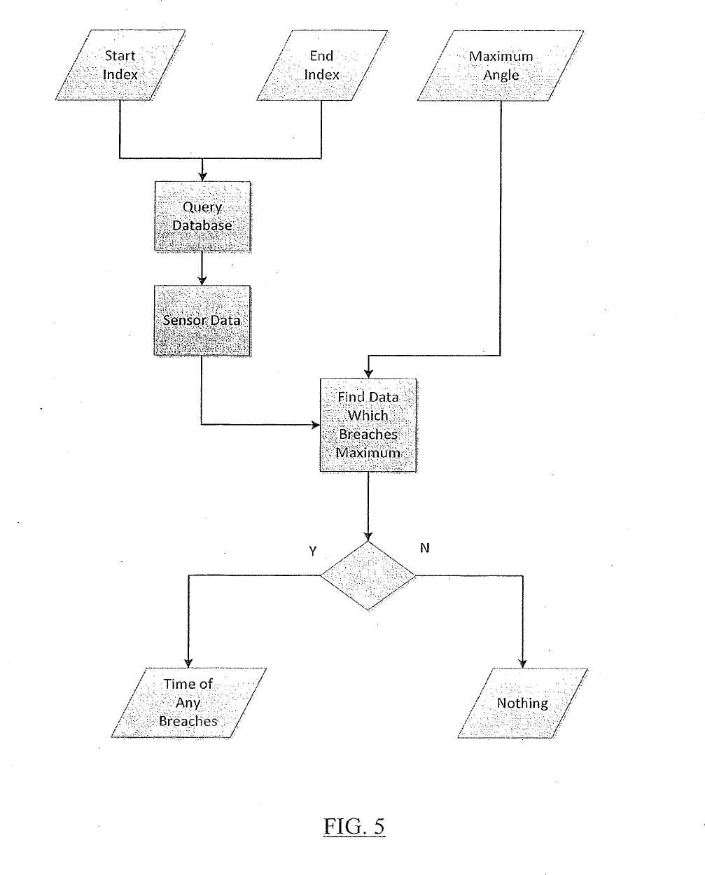

With reference to FIG. 5, Maximum Roll Angle Value may also be calculated. Database 30 is loaded and queried for sensor data from the IMU 20 to determine if the maximum allowed roll angle has been exceeded. The database elements are then compared with the Maximum Alarm Value. The result of Alarm ON or Off is returned and this Boolean value of alarm state is recorded in the database. The database is then queried by other routines that act on the alarm status value.

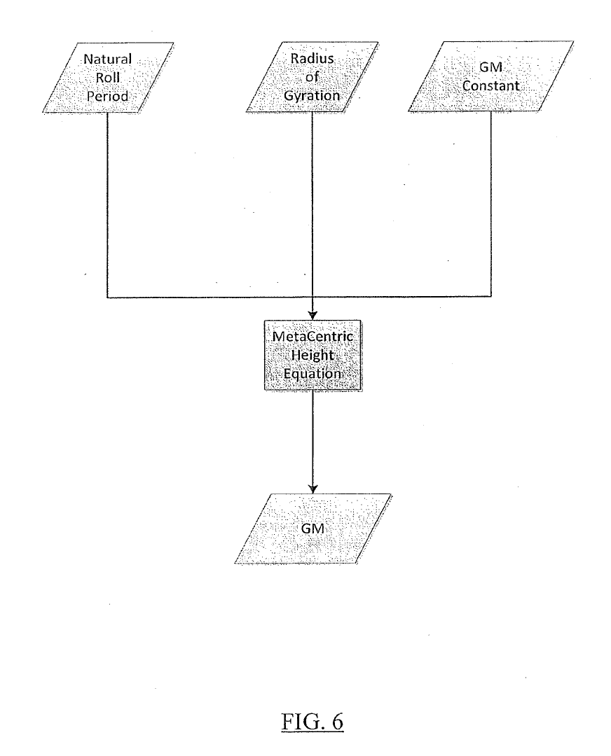

With reference to FIG. 6, GM (Metacentric Height) is calculated from the Roll Period. The Natural Roll Period can be derived in known calculations from the Natural Frequency. Using instrument-calculated Natural Roll Period taken from the Natural Frequency from FIG. 2, 3 and the registered Radius of Gyration for the vessel as well as the particular vessel's GM Constant, the GM routine calculates the current GM value. The Radius of Gyration is unique to a given vessel and is derived from the hydrostatic curves as prepared by a Naval Architect. The GM constant is unique to a type of vessel, and from the Principles of Naval Architecture (page 78) the GM Constant is 0.8 for surface vessels, where units are metric. The GM is then calculated as follows:

GM=(GM_CONSTANT*RADIUS_OF_GYRATION/NATURAL_ROLL_PERIOD)²

The following states calculated by processor 28 will generate an alarm signal whether audible or visual or both:
1 Large Angle Roll
2 Small GM
3 Large Acceleration
4 Sudden Humidity Change
5 Unauthorized Power Cycle
6 List—Static
7 List—Dynamic
8 Generic Malfunction
9 CPU Failure
10 Back-up battery minimum voltage
11 Photon Detector
12 Other User-specified alarms

The accelerometer in IMU 20 can also detect an impact which can cause processor 28 to generate an alarm signal.

The System has optional functions which may include: i) Battery-operated smart router that connects a local mobile device or computer network to a global monitoring system and which ii) relays information about guidance and telemetry, GPS, weather, background radiation, temperature, and humidity; iii) a standalone power management system with diesel electric hybrid engine management and autonomous guidance system, with dynamically updated safety information from radar and sonar; iv) fleet management and tracking for insurance companies, relaying realtime usage and location information; v) tamper proof data collection and management with internal tamper proof time codes; vi) stand alone and tamper proof AIS system (Automatic Identification System) information and management; vii) additional information about fuel, ballast, and cargo stability relayed to a central location via a mobile connected network; viii) standalone backup power system with charge management system for long term diagnostic monitoring and forensic recovery of incidents that occur on or near vessel on which it is deployed; ix) system wide power watchdog to alert vessel owners and operators of power failures, fuel status etc.; x) safety relay monitoring information about crew and/or cargo relayed via a mobile device or connected computer through the programmable device network or secondary programmable logic device monitoring system control; xi) integration with PLD (programmable logic device) Human Machine Interface system relaying state information from said device to operators on existing platforms while providing secure connectivity and report tunneling to central authority; xii) a security tool for monitoring position of assets while providing capability to remotely inhibit and or enable reactive systems to mitigate problems; xiii) predictive range path planning with alarm state to notify operator of possible events such as strandings from fuel problems; Weather warning system, fire warning system, operator inactivity, schedule deviation, proximity of unauthorized boardings, such as piracy; xiv) integration with power grids and oceanographic equipment communication infrastructure, radar infrastructure, submersible and surface vessels; xv) platform monitoring for abnormal drilling activity, mechanical noises, seismic activity, refinement and inventory control, counting information; xvi) control of said subsystems via remote links; Information exchange, updates, and operator notification; xvii) Protocol translation and network protocol adaption; xviii) system monitoring, security auditing and monitoring, operational load monitoring, power system monitoring and control, integration with solar wind, petrochemical, and nuclear power systems, Air quality monitoring systems, Atmospheric monitoring systems, Explosive gas monitoring systems, Toxic chemical monitoring systems, Medical monitoring systems, such as blood sugar levels, oxygen levels, diagnostic equipment; xix) Tow monitoring systems, tension diagnostic monitoring systems, corrosion monitoring systems, stress monitoring systems, fatigue, cracks ruptures and leak monitoring systems.

The System has other optional features which may include: xx) Social network integration, such as reporting public information to a global network such as Twitter™; xxi) Cell phone integration, such as a docking station or wireless connectivity, not necessarily network; xxii) Global payment and subscription management, and accounting integration, accounts for fuel consumption and for cost optimized voyages; xxiii) Inert gas atmosphere monitoring, atmospheric gas monitoring such as cryogenic systems; xxiv) Interface and headless operation (“headless” meaning without a screen); xxv) Vocal text-to-speech as well as remote operator communication; xxvi) Optical system interface; xxvii) Acoustic interface system; xxviii) Radar based interface; xxix) Pneumatic and hydraulic system interface; xxx) Salinity and buoyancy monitoring, water temperature monitoring.

### Power Supply Process

Preferably the power supply accepts a wide range of DC and AC voltage power supply input (from 9 v-48 v DC, up to 110 v AC), irrespective of input polarity. Power Rectification, regulation and distribution for multiple sensor and ancillary loads; and built in noise suppression with filtration to prevent noise from feeding back into supply system is also provided. Computer controlled step down conversion, including system control and monitoring algorithms with thermal protection and shut down with current limiting routines are included.

Undervoltage protection can be via Schottky diode. An efficient toroidal transformer may supply the second stage of step down conversion for power delivery to the processor. This takes it to 3.3 v for low voltage high speed logic controls and sensors. A bypass protection diode for secondary voltage converter may also be provided. The power conversion and regulation is thereby ready for distribution to ancillary components not limited to the processor, MU, GPS, humidity and temperature etc.

The humidity sensor is used to insure tamper proof integrity of the system, triggering shut down and communication protocols to defend against intrusion. A photo detector circuit may also be added to provide a redundant tamper proof system. A silicon conformal coating over the entire system may serve to prevent corrosion and associated failure.

A microprocessor-controlled charge management system functioning in a similar fashion to a trickle charge device, that provides backup battery protection with instant switch-over for sustained operation of the system with a separate supervisory microprocessor for power level monitoring may be provided. This may include a battery discharge limit to ensure resuscitation and data recovery, and provides an orderly shut down routine, to ensure data storage and prevent system brown out. It triggers a system status message transmitted via com ports to alert of power disconnect or failure. If there is a short, the battery is isolated via a diode-protected non latching relay whose failure mode is normally open to ensure overall system safety. This provides a system-wide power watchdog to alert vessel owners and operators of power failures, fuel status etc.

### Power Management

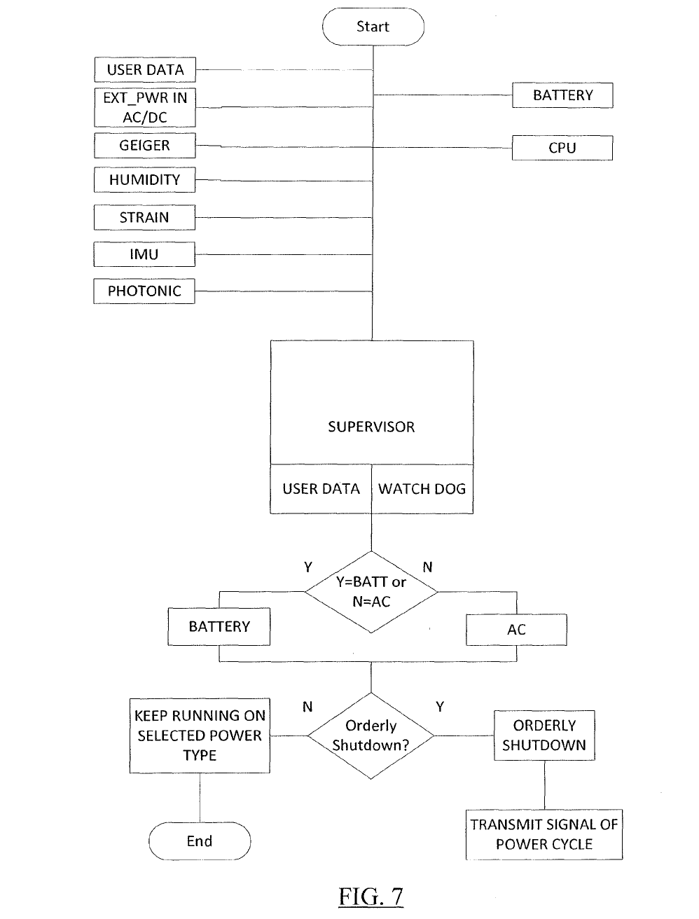

With reference to FIG. 7, the system may incorporate a step-down converter that can accept a wide variety and range of DC and AC input with built-in battery charging. When the monitoring circuitry senses that the main supply drops below the minimum voltage threshold the battery takes over supplying power to the system by switching over to the regulator's input. On-board supervisory circuitry monitors overall power management. If the power is shut off and the supervisor circuit determines it has been out for longer than allowable (typically about 5 minutes) and the voltage sensed is less than the minimum threshold voltage, then the host system is notified to commence with orderly shut-down of the device to ensure system integrity with no brown-outs because the supervisory system needs to clean power. The system is notified and is sent a wireless notification of the power cycle. The supervisor circuitry has a Geiger counter, strain gauge as well as a humidity and photonic sensor that performs backplane monitoring. The system self-resets if a watchdog timer senses it is unresponsive.

While a wireless communication system has been described for communicating sensor measurements to the processor 28, such communication may also be wired. While the measurements from various sensors are preferred to be continuous, the practical restrictions of communication networks may require that such measurements and/or communications of such communications are periodic. The term “continuous” is intended to encompass such periodic measurements which are for practically purposes continuous.

While a number of exemplary aspects and embodiments have been discussed above, those of skill in the art will recognize certain modifications, permutations, additions and sub-combinations thereof. It is therefore intended that the following appended claims and claims hereafter introduced are interpreted to include all such modifications, permutations, additions and sub-combinations as are within their true scope.

What is claimed is:

1. A method of automated continuous monitoring of the stability of a vessel comprising:
i) providing on said vessel a digital accelerometer, a digital gyroscope, and a digital magnetometer;
ii) providing a processor comprising a computer processor, data storage and computer code which when executed carries out mathematical calculations and comparisons based on input signals and generates output signals based on said mathematical calculations and comparisons;
iii) communicating periodic or continuous measurement signals from said accelerometer, gyroscope and magnetometer to said processor;
iv) said processor using said measurement signals to calculate a natural frequency of roll of said vessel at successive points of time;
v) said processor calculating a natural roll period of said vessel from said natural frequency at successive points of time;
vi) said processor calculating the metacentric height of said vessel at successive points of time from said natural roll period;
vii) said processor comparing the calculated metacentric height of said vessel at successive points of time to a predefined limit; and
viii) issuing an alarm if said calculated metacentric height of said vessel at a point of time is less than said predefined limit.

2. The method of claim 1 further comprising the steps of:
ix) providing a Global Positioning System receiver to provide positioning, time and velocity data to said processor, and
x) computer code which when executed by said processor enables said processor to correct the time and/or velocity used in said calculation of natural frequency.

3. The method of claim 1 or 2 further comprising the steps of:
xi) said processor calculating the mean incline of said vessel at successive points of time;
xii) said processor comparing the mean incline of said vessel at successive points of time to a predefined upper limit; and
xiii) issuing an alarm if said mean incline of said vessel at a point of time is greater than said predefined limit.

4. The method of claim 1, 2 or 3 further comprising the steps of:
xiv) said processor calculating the maximum roll angle value of said vessel at successive points of time;
xv) said processor comparing the maximum roll angle value of said vessel at successive points of time to a predefined upper limit; and
xvi) issuing an alarm if said maximum roll angle value of said vessel at a point of time is greater than said predefined limit.

5. The method of claim 1, 2, 3 or 4 further comprising:
xvii) providing one or more additional sensors communicating measurement data to said processor, wherein said sensors are selected from the group consisting of temperature sensors, humidity sensors, strain forces sensors, background radiation level sensors, fuel level sensors, ballast level sensors, and cargo stability sensors;
xii) said processor comparing the measurement data provided by said one or more additional sensors at successive points of time to a predefined upper or lower limit; and
xiii) issuing an alarm if said measurement data provided by said one or more additional sensors at successive points of time is greater or less than said predefined upper or lower limit.

6. The method of claim 1 further comprising the steps of:
ix) providing a primary power supply and a back-up battery;
x) said processor switching from said primary power supply to said backup battery when said primary power supply drops below a minimum voltage; and
xi) said processor providing an orderly shut down routine to ensure data storage if power is shut off or less than a specified voltage for a period greater than a maximum allowable period.

7. A system for automated continuous monitoring of the stability of a vessel comprising:
i) a digital accelerometer;
ii) a digital gyroscope;
iii) a digital magnetometer;
iv) a processor comprising a computer processor, data storage and computer code which, when executed, carries out mathematical calculations and comparisons based on input signals and generates output signals based on said mathematical calculations and comparisons;
v) a communication network for periodically or continuously communicating measurement signals from said accelerometer, gyroscope and/or magnetometer to said processor; and
vi) an alarm for generating a visual and/or audible alarm signal;
wherein said computer code, when executed, uses said measurement signals to calculate a natural frequency of roll of said vessel at successive points of time, a natural roll period of said vessel from said natural frequency at successive points of time, and the metacentric height of said vessel at successive points of time from said natural roll period, compares the calculated metacentric height of said vessel at successive points of time to a predefined limit, and communicates an alarm if said calculated metacentric height of said vessel at a point of time is less than said predefined limit.

8. The system of claim 7 further comprising:
v) a Global Positioning System receiver to provide positioning, time and velocity data to said processor, and
vi) computer code which when executed by said processor enables said processor to correct the time and/or velocity used in said calculation of natural frequency.

9. The system of claim 7 or 8 wherein said communication network for periodically or continuously communicating measurement signals from said accelerometer, gyroscope and/or magnetometer to said processor comprises a wireless network.

10. The system of claim 7, 8 or 9 further comprising one or more additional sensors communicating measurement data to said processor, wherein said sensors are selected from the group consisting of temperature sensors, humidity sensors, strain forces sensors, background radiation level sensors, fuel level sensors, ballast level sensors, and cargo stability sensors.

11. The system of claim 7, 8, 9 or 10 further comprising a primary power supply and a back-up battery whereby said processor is programmed to switch from said primary power supply to said backup battery when said primary power supply drops below a minimum voltage.

12. The system of claim 11 whereby said processor is further programmed to provide an orderly shut down routine to ensure data storage if power is shut off or less than a specified voltage for a period greater than a maximum allowable period.
